(19) United States
(12) Patent Application Publication
(10) Pub. No.: US 2011/0168784 A1
(43) Pub. Date: Jul. 14, 2011

(54) Wireless Communication Device for Remote Authenticity Verification of Semiconductor Chips, Multi-Chip Modules and Derivative Products

(75) Inventor: Chang-Ming Lin, San Jose, CA (US)

(73) Assignee: RFMARQ, INC., Monte Sereno, CA (US)

(21) Appl. No.: 12/977,042

(22) Filed: Dec. 22, 2010

Related U.S. Application Data
(60) Provisional application No. 61/295,159, filed on Jan. 14, 2010.
(60) Provisional application No. 61/316,822, filed on Mar. 23, 2010.

(51) Int. Cl. G06K 19/077; H01L 21/50

(52) U.S. Cl. 235/492; 438/118; 257/E21.499

(57) ABSTRACT

A wireless tag includes a wireless transceiver, a memory and an antenna all formed on a flexible thin film substrate. The wireless tag is inserted into the packaging material of a microelectronic device to implement tracking and authentication functions. In some embodiments, the wireless communication device stores identity or other identification information for the microelectronic device, and/or the derivative system product incorporating the microelectronic device. The wireless tag may be embedded in the packaging of the microelectronic device. In one embodiment, the wireless tag is embedded in the packaging of a multi-chip package module housing one or more integrated circuits. In this manner, the wireless communication device can be used to track and authenticate the integrated circuits as well as the derivative system products incorporating the integrated circuits.

### CROSS-REFERENCE TO RELATED APPLICATIONS

This application claims the benefit of U.S. Provisional Patent Application Ser. No. 61/295,159, filed on Jan. 14, 2010, and U.S. Provisional Patent Application Ser. No. 61/316,822, filed on Mar. 23, 2010, which applications are incorporated herein by reference in their entireties.

This application is related to copending and commonly assigned U.S. patent application Ser. No. 12/841,021, entitled “System and Method To Track And Authenticate Semiconductor Chips, Multi-Chip Package Modules, And Their Derivative System Products,” filed Jul. 21, 2010, of the same inventor hereof, which application is incorporated herein by reference in its entirety.

This application is related to concurrently filed and commonly assigned U.S. patent application Ser. No. ______, entitled “System and Method To Embed A Wireless Communication Device Into Semiconductor Packages” (Attorney Docket No. RFM-P011-2D), U.S. patent application Ser. No. ______, entitled “System and Method To Embed A Wireless Communication Device Into Semiconductor Packages” (Attorney Docket No. RFM-P011-3D), and U.S. patent application Ser. No. ______, entitled “System and Method To Embed A Wireless Communication Device Into Semiconductor Packages, including Chip-Scale Packages and 3D Semiconductor Packages” (Attorney Docket No. RFM-P011-4D), all of the same inventor, which applications are incorporated herein by reference in their entireties.

### FIELD OF THE INVENTION

The invention relates to wireless communication devices and, in particular, the invention relates to wireless communication devices embedded in semiconductor packages.

### DESCRIPTION OF THE RELATED ART

Consumer electronic products can be tagged using electronic tracking devices or electronic tags to store product identity or other product information to allow the products to be tracked through the manufacturing process or through the supply and distribution chain. Electronic tags are electronically read by electronic readers (communicators) when the tags are within the communication range.

Radio frequency identification (RFID) technology is an electronic tracking technology commonly employed to track products and their movements. An RFID tag includes a wireless transceiver device and an antenna to enable radio frequency (RF) communication between the RFID tag and an RFID reader when the reader is brought within a communication range of the tag. The RFID transceiver device includes storage elements for storing identity or product information, and a circuit to receive incoming signals, generate response signals and transmit the response signals.

When RFID tags are affixed to electronic products, the RFID tags are often subject to easy tampering. For example, if the RFID tag is merely placed on the chassis or even on internal printed circuit board of an electronic product, the RFID tag can be removed to prevent tracking of the product.

### SUMMARY OF THE INVENTION

According to one embodiment of the present invention, a wireless tag, for tracking identity or identification information, includes a flexible thin film substrate, an antenna structure formed on the flexible thin film substrate, and a wireless element including a wireless transceiver and a memory circuit formed on one or more integrated circuit chips. The one or more integrated circuit chips are affixed to the flexible substrate and electrically connected to the antenna structure and the memory circuit has at least identity or identification information stored thereon. The wireless transceiver and the antenna structure operate in conjunction to enable the information stored in the memory circuit to be accessed through wireless communication.

According to another aspect of the present invention, methods for embedding a wireless tag into various types of semiconductor packages are described.

In one embodiment, a method for providing identity tracking and authentication for a multi-chip package (MCP) module or one or more integrated circuits formed on a multi-chip package (MCP) base of the MCP module includes providing a wireless tag including a wireless element including a wireless transceiver and a memory circuit formed on one or more integrated circuits where the wireless element is affixed to a flexible substrate having an antenna formed thereon and the wireless element is electrically connected to the antenna and the memory circuit has at least identity or identification information stored thereon and wherein the wireless transceiver and the antenna structure operate in conjunction to enable the information stored in the memory circuit to be accessed through wireless communication, affixing the wireless tag to the MCP base of the MCP module, and completing the MCP module with the wireless tag and the one or more integrated circuits enclosed therein.

### BRIEF DESCRIPTION OF THE DRAWINGS

FIGS. 1(a) and 1(b) are cross-sectional and perspective views of a wireless communication device (also referred as “a wireless tag”) according to one embodiment of the present invention.

FIG. 2 illustrates the different embedding methods which can be used to embed a wireless tag into a semiconductor package according to embodiments of the present invention.

FIGS. 3(a) and 3(b) illustrate two methods of embedding a wireless tag into a plastic encapsulated semiconductor package according to embodiments of the present invention.

FIGS. 4(a) and 4(b) illustrate two methods of embedding a wireless tag into a lid-sealed semiconductor package according to embodiments of the present invention.

FIGS. 5(a) and 5(b) illustrate two methods of embedding a wireless tag into the encapsulation material of an encapsulated semiconductor package according to embodiments of the present invention.

FIGS. 6(a) and 6(b) illustrate two methods of embedding a wireless tag into the filler insulator material of a lid-sealed semiconductor package according to embodiments of the present invention.

FIG. 7 is a schematic diagram of a MCP base incorporating a wireless tag according to one embodiment of the present invention.

FIGS. 8(a) to 8(d) illustrate methods of embedding a wireless tag into a lid-sealed semiconductor package according to embodiments of the present invention.

FIG. 9 illustrate a method for embedding a wireless tag onto a chip scale package according to one embodiment of the present invention.

FIGS. 10(a) and 10(b) illustrate two methods of embedding a wireless tag onto a Through Silicon Vias (TSV) 3D semiconductor package according to embodiments of the present invention.

FIGS. 11(a) and 11(b) are top and cross-sectional views of a wireless tag implemented using a wireless element configured as two integrated circuit chips according to one embodiment of the present invention.

### DETAILED DESCRIPTION OF THE PREFERRED EMBODIMENTS

According to one aspect of the present invention, a wireless communication device including a wireless transceiver, a memory and an antenna all formed on a flexible thin film substrate is inserted into the packaging material of a microelectronic device to implement tracking and authentication functions for the microelectronic device and/or the derivative electronic system incorporating this microelectronic device. In some embodiments, the wireless communication device stores identity or other identification information for the microelectronic device, and/or the derivative system product incorporating the microelectronic device. In this manner, the same wireless communication device can be used to track and authenticate the microelectronic device as well as the derivative system products incorporating the microelectronic device. More specifically, the information stored in the memory of the wireless communication device may be accessed by a wireless reader when the wireless communication device comes within the communication range of the reader. For instance, the information stored in the memory may be accessed in order to read out or to alter the stored information.

The wireless communication device of the present invention can be readily adapted for use in a variety of semiconductor package types to allow tracking and authentication function to be implemented at low cost and with simple manufacturing steps. Furthermore, by embedding the wireless communication device into the packaging of the microelectronic device, the wireless communication device is protected from tampering, further ensuring the authenticity of the microelectronic device and/or its derivative system product.

In embodiments of the present invention, a microelectronic device includes semiconductor packages containing a single integrated circuit chip or multiple integrated circuit chips. The semiconductor packages may be formed of various materials, including plastic, ceramic, and other semiconductor packaging materials. A semiconductor package housing two or more integrated circuits (chips) is sometimes referred to as a multi-chip package (MCP) or a MCP module or a multi-chip module (MCM). Examples of semiconductor packages in which the wireless communication device of the present invention can be embedded include plastic ball grid array (PBGA) packages, ceramic ball grid array (CBGA) packages, land grid array (LGA) packages, plastic quad flat packages (PQFP), low-profile quad flat packages (LQFP), and other semiconductor packages. In the present description, the term “semiconductor package” refers to both single chip packages or multi-chip packages (MCP).

### Wireless Communication Device

In embodiments of the present invention, a wireless communication device, also referred to as “a wireless tag,” is preformed or manufactured as a standalone element for embedding into a semiconductor package.

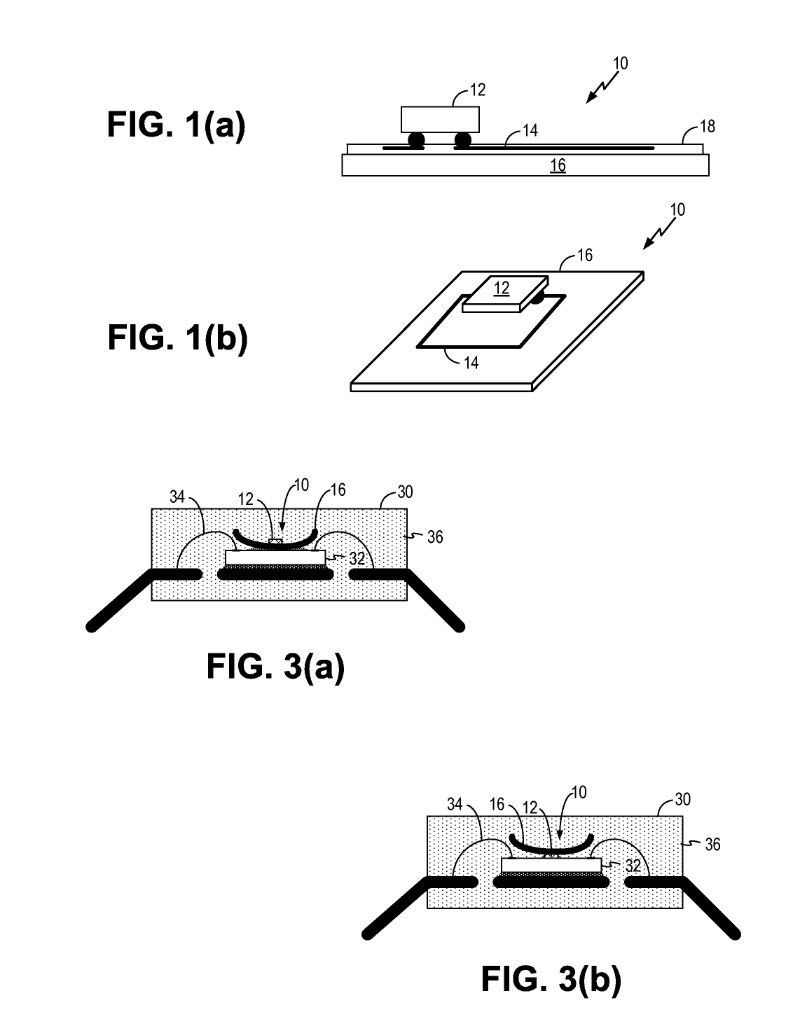

FIGS. 1(a) and 1(b) are cross-sectional and perspective views of a wireless communication device (“a wireless tag”) according to one embodiment of the present invention. Referring to FIGS. 1(a) and 1(b), a wireless tag 10 includes a wireless transceiver and a memory, referred to collectively as a wireless element 12, are formed as a single integrated circuit chip. In the present description, a wireless element refers to the combination of the wireless transceiver circuit and the memory circuit and may be formed as one or more integrated circuit chips, as will be described in more detail below. The wireless element 12 and a metallic antenna structure 14 are formed on a flexible thin film substrate 16 (“flexible substrate”). In the present embodiment, the wireless element 12 is flip-chip attached to the antenna structure 14. In one embodiment, the wireless element 12 is affixed to the antenna structure using solder-bump reflowed.

In some embodiments, the flexible substrate 16 is formed from polymer films. Examples of this polymer films include, but are not limited to, polyethylene terephthalate (PET), Kapton, polyimide or mylar flexible polymer films.

In some embodiments, the metallic antenna structure 14 is formed using a single layer of metal film or using a multi-layer metal structure with intercalated dielectric films as isolation and interconnect via(s) to bridge different metal layers. The metal films and dielectric films can be formed using sputtering deposition, evaporation coating, electroplating, laminating or printing or other deposition methods. In one embodiment, the antenna structure is formed by depositing a metal film into a pattern preformed by photoresist (or equivalent materials). In another embodiment, the antenna structure is formed by depositing a metal layer on the substrate and patterning or masking the metal layer using a photoresist. The masked metal layer can then be processed using etching techniques, including wet metal etch or dry metal etch or a combination of both. In some embodiments, a passivation dielectric layer 18 is formed over the metallic antenna structure 14 to protect the as-fabricated antenna structure. However, the passivation dielectric layer 18 is optional and may be omitted in other embodiments of the present invention. The above-described metal antenna fabrication methods are illustrative only and are not intended to be limiting. Other fabrication methods for forming the metal antenna can be used.

In the present embodiment, the wireless element 12 of the wireless tag 10 is affixed to contact pads of the metallic antenna structure 14 by means of flip-chip attachment as shown in FIGS. 1(a) and 1(b). The flip-chip attachment can be accomplished using a variety of techniques, including anisotropic conductive adhesives (ACA), conductive inks, conductive pastes, gold bumps, solder bumps, or other bumps formed by low melting point metals or alloys. In some embodiments, an underfiller and/or a globtop material may be applied to further enhance the mechanical bonding integrity of the electrically conductive joints between wireless element and the antenna contact pads. In other embodiments, other methods for affixing the wireless element 12 to the antenna structure 14 may be used. The use of flip-chip attachment is illustrative only and is not intended to be limiting.

As thus formed, a stand-alone wireless tag 10 is realized which can be embedded into a semiconductor package to realize tracking and authenticating functions. The preformed wireless tag can be inserted into plastic molding material of a plastic semiconductor package or inserted into the package cavity of a lid-sealed semiconductor package. In order for the wireless tag to be incorporated into a semiconductor package, the wireless tag is typically no larger and no thicker than the size of the semiconductor package.

In the above described embodiment, a single integrated circuit (wireless element 12) houses both the wireless transceiver and the memory on a single integrated circuit. In other embodiments, the wireless transceiver and the memory circuit can be formed as two or more integrated circuits (chips), all of the integrated circuits being interconnected on the substrate to form the wireless tag. The exact level of integration of the wireless transceiver and the memory of the wireless tag is not critical to the practice of the present invention. In the present description, the term “a wireless element” refers to the combination of a wireless transceiver circuit and a memory circuit formed in one or more integrated circuits (i.e. one or more chips).

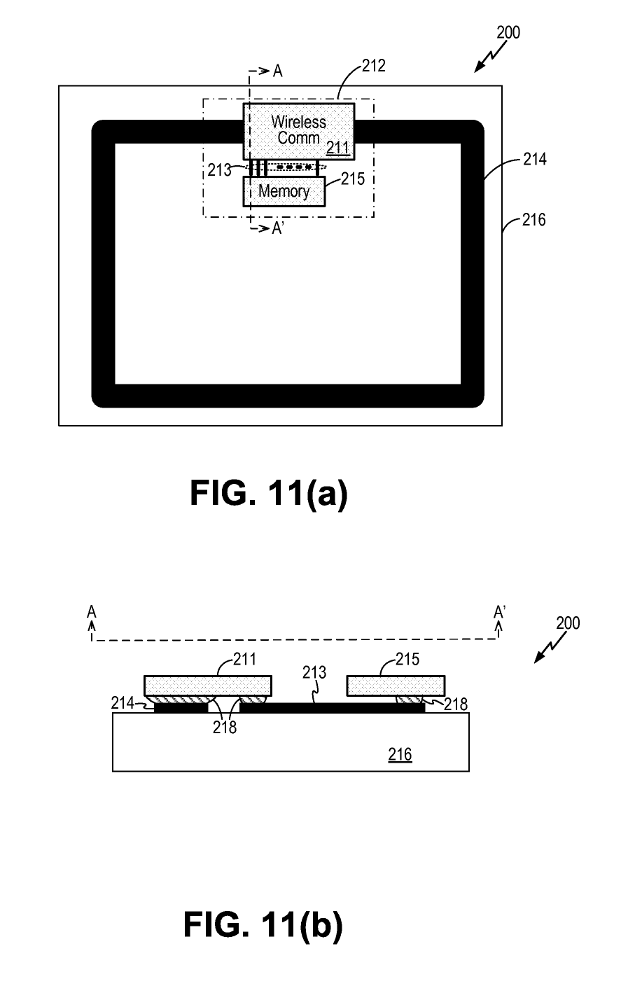

FIGS. 11(a) and 11(b) are top and cross-sectional views of a wireless tag implemented using a wireless element configured as two integrated circuit chips according to one embodiment of the present invention. Referring to FIGS. 11(a) and 11(b), a wireless tag 200 includes a wireless element 212 formed as two integrated circuit chips and a metallic antenna structure 214 formed on a flexible thin film substrate 216 (“flexible substrate”). In the present embodiment, the wireless element 212 includes a wireless transceiver integrated circuit 211 and a memory integrated circuit 215. The wireless transceiver IC 211 and the memory IC 215 are interconnected through metal interconnects 213 formed on the flexible substrate 216. In some embodiments, metal interconnects 213 and metal antenna 214 can be formed using the same metal deposition methods, including evaporation coating method, sputtering deposition method, electrolytic deposition method, electrochemical deposition method or by thin metal foil lamination. In the present embodiment, the wireless transceiver IC 211 is flip-chip attached to the antenna structure 214 and the memory IC 215 is flip-chip attached to the metal interconnects 213, as shown in the cross-section of FIG. 11(b). Furthermore, in the present embodiment, the flip-chip attachment is realized using solder bumps 218. In other embodiments, the flip-chip attachment can be realized using anisotropic conductive adhesives (ACA). In some embodiments, an underfill material may be used to secure the solder bump joints. The underfill material can be one of a polymer material, a polymeric composite with inorganic filler(s), or epoxies.

Furthermore, in the above-described embodiments, the integrated circuit(s) forming the wireless element is flip-chip attached to the flexible substrate. In other embodiments, the integrated circuit(s) of the wireless element may be connected to the flexible substrate, the antenna and the metal interconnects (if any) through other bonding and electrical connection techniques, including wire bonding. In some embodiments, the integrated circuits of the wireless element are attached to the substrate using die attach and then the integrated circuits are wire bonded to the antenna and the metal interconnects (if any). In some embodiments, a globtop material or suitable polymer, such as epoxy or silicone, may be applied to protect the wire bonds.

In embodiments of the present invention, the wireless communication device stores at least identity or identification information of the microelectronic device in the memory of the wireless element of the wireless tag. In other embodiments, the wireless communication device stores at least identity or identification information of the derivative system products incorporating the microelectronic device in the memory of the wireless element of the wireless tag. In the present description, “identity” or “identification information” of a microelectronic device includes the identification number, part number, model number, model name, brand name, maker, logo design, and production and/or distribution history of the microelectronic device. Furthermore, identity or identification information can include a software code or an algorithm to generate an identity code in response to interrogations from a wireless reader or other systems. In embodiments of the present invention, the data format of the identification information includes a random or serial numerical numbers or characters, logo marks, graphic symbols, 2D graphic codes, or any multiplex permutation of these formats. Other encoding or algorithms methods currently known or to be developed can also be used. In an alternate embodiment, the identity or identification information stored in the wireless element is protected through the use of encryption or software keys or other feasible security protection methods presently known or to be developed.

Also, in the present embodiment, the wireless communication device is capable of wireless communication employing one or more of the wireless communication technologies currently known or to be developed. For example, in one embodiment, the wireless communication device implements wireless communication through radio frequency (RF) communication, such as based on the RFID (radio frequency identification) technology, or wireless local area network communication technology, such as Wi-Fi technology. In another embodiment, the wireless communication device employs Bluetooth radio technology. Bluetooth radio technology is an open specification for short-range wireless communication of data and voice that operates in the unlicensed Industrial, Scientific, Medical (ISM) band at 2.4 Gigahertz (GHz). The gross data rate may be 1 megabit per second (Mb/s). In yet another embodiment, the wireless communication device employs ZigBee communication technology. ZigBee is a wireless control technology utilizing a low-cost, low power, wireless mesh networking protocol that is especially useful in control and monitoring applications. In yet another embodiment, the wireless communication device employs WiMAX communication.

### Methods for Embedding Wireless Tag in Semiconductor Package

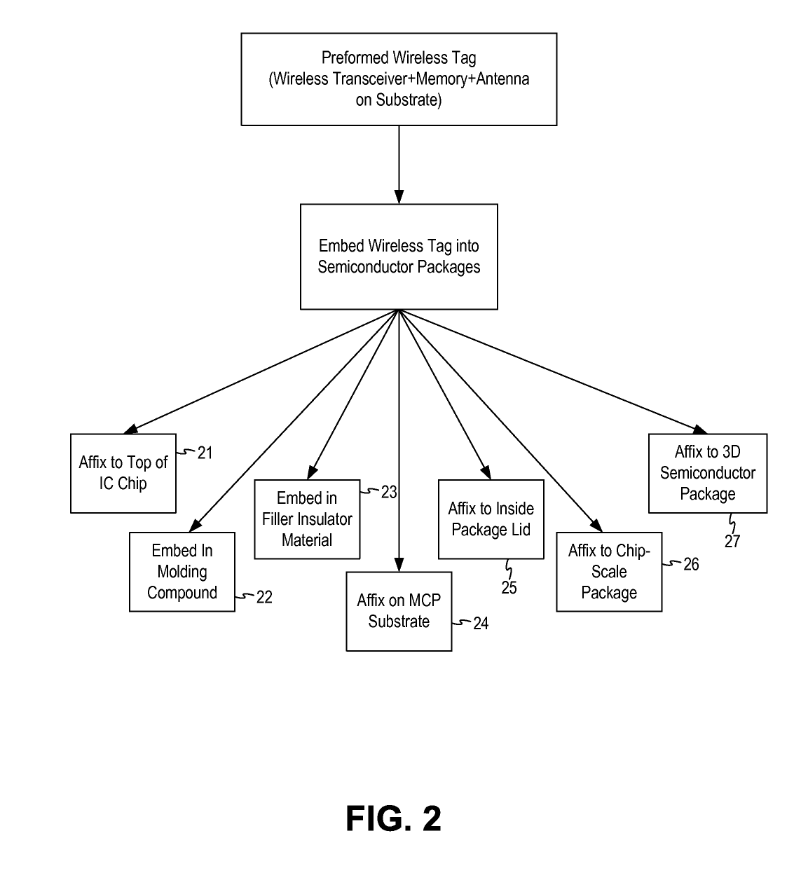

According to another aspect of the present invention, methods for embedding the wireless tag into various types of semiconductor packages are described. FIG. 2 illustrates the different embedding methods which can be used to embed a wireless tag into a semiconductor package according to embodiments of the present invention. Referring to FIG. 2, first, a preformed wireless tag is provided. The wireless tag includes a wireless transceiver, a memory and an antenna all formed on a substrate. The wireless transceiver and the memory, collectively referred to as a “wireless element,” may be formed on one or more integrated circuits.

In some embodiments, the wireless tag is formed on a flexible substrate and is constructed as described above with reference to FIGS. 1(a) and 1(b) and FIGS. 11(a) and 11(b). In other embodiments, the wireless tag may be constructed in the same manner as described above except the wireless transceiver, the memory and the antenna are formed on a thin rigid substrate. For instance, the thin rigid substrate may be formed of an oxide material including glass or ceramic. The thin rigid substrate may also be formed using composite materials, such as FR4 with glass fiber. In some embodiments, the thin rigid substrate has a thickness of less than 1 mil. to several mils.

With a wireless tag thus provided, the wireless tag can then be embedded into a semiconductor package using one of various embedding methods depending on the package type and other requirements.

In one embodiment, the wireless tag is affixed to a top surface of an integrated circuit (“IC chip”) housed in the semiconductor package (method 21). The semiconductor package may be a plastic package which encapsulates the IC chip or a ceramic package which houses the IC chip in a package cavity.

In another embodiment, the wireless tag is embedded in the plastic molding compound of a plastic semiconductor package (method 22).

In a further embodiment, the wireless tag is embedded in the filler insulator material used to fill the package cavity of a lid-sealed semiconductor package (method 23).

In another embodiment, the semiconductor package is a multi-chip package (MCP) including a multilayer interconnect substrate. Accordingly, the wireless tag is affixed to the multilayer interconnect substrate of the MCP package (method 24).

In another embodiment, the wireless tag is affixed to the inside of a package lid for a lid-sealed semiconductor package (method 25).

In a further embodiment, the wireless tag is affixed and encapsulated onto a chip-scale package (CSP) (method 26).

In another embodiment, the wireless tag is affixed to a Through Silicon Vias (TSV) three dimensional (3D) semiconductor package (method 27).

The embedding methods shown in FIG. 2 will be described in more detail below. While FIG. 2 illustrates various embedding methods, FIG. 2 is illustrative only and is not intended to be limiting. Other embedding methods for various package types are possible.

### Affix Wireless Tag to Top Surface of IC Chip

In embodiments of the present invention, a wireless tag is embedded in a semiconductor package by being affixed to an exposed top surface of an integrated circuit chip (IC chip) housed in the semiconductor package. The wireless tag is completely enclosed and contained inside the packaging materials of the semiconductor package. In these embodiments, a wireless tag formed on a flexible substrate is preferred.

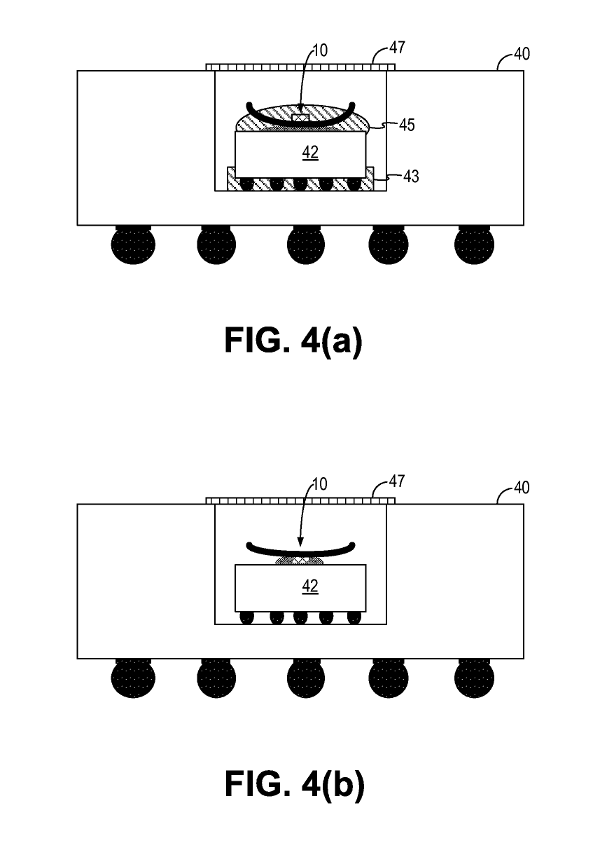

FIGS. 3(a) and 3(b) illustrate two methods of embedding a wireless tag into a plastic encapsulated semiconductor package according to embodiments of the present invention. More specifically, the wireless tag can be affixed to the IC chip surface in one of two orientations—wireless-element-up (FIG. 3(a)) or wireless-element-down (FIG. 3(b)). First, as shown in FIG. 3(a), in a plastic encapsulated semiconductor package 30 housing an IC chip 32, the wireless tag 10 is affixed to the exposed top surface of the IC chip 32 in the wireless-element-up orientation. That is, the wireless element 12 of the wireless tag 10 is facing away from the IC chip 32 and the wireless tag 10 is affixed to the IC chip 32 through the flexible substrate 16. Second, as shown in FIG. 3(b), the wireless tag 10 is affixed to the exposed top surface of the IC chip 32 in the wireless-element-down orientation. That is, the wireless element 12 of the wireless tag 10 is facing towards the IC chip 32 and the wireless tag 10 is affixed to the IC chip 32 through the wireless element 12. For either of the affixation orientations, the wire bonds 34 of the semiconductor package 30 should be electrically insulated and/or mechanically secured prior to the wireless tag affixation. After the wireless tag is affixed to the IC chip 32, the semiconductor package 30 can be completed by encapsulating the package structure using an encapsulant 36, such as epoxy or appropriate plastics. In this manner, the wireless tag 10 is encapsulated with the IC chip 32 in the encapsulant material 36. FIGS. 4(a) and 4(b) illustrate two methods of embedding a wireless tag into a lid-sealed semiconductor package according to embodiments of the present invention. In the embodiments shown in FIGS. 4(a) and 4(b), the IC chip 42 is housed in the package cavity of the lid-sealed semiconductor package 40 and is affixed to the package soldering pads through flip-chip attachment. Thus, the surface of the IC chip 42 facing the package lid 47—the “top surface”—is now the backside of the IC chip. In some cases, the semiconductor package 40 may use an underfiller material 43 applied between the solder joints or bump joints of the IC chip 42 and the package soldering pads. The use of underfiller material 43 is optional.

For the flip-chip-attached semiconductor package 40, the wireless tag 10 can be affixed to the backside of the IC chip 42 in the wireless-element-up orientation where the flexible substrate of the wireless tag 10 is affixed to the backside of the IC chip 42, as shown in FIG. 4(a). Alternately, the wireless tag 10 can be affixed to the backside of the IC chip 42 in the wireless-element-down orientation where the wireless element of the wireless tag 10 is affixed to the backside of the IC chip 42, as shown in FIG. 4(b).

In some embodiments, after the wireless tag is affixed to the backside of the IC chip 42, the wireless tag10 can be encapsulated with a protective layer 45 before the lid sealing process. The protective layer 45 can be selected from one of a globtop material, a thermal interface material 2 (TIM2), an epoxy, and a silicone encapsulant material. In embodiments of the present invention, the package lid 47 can be a plastic lid, a ceramic lid, a metal lid, a glass lid, or other types of package lids.

In embodiments of the present invention, the wireless tag is affixed to the IC chip using epoxy adhesion or other equivalent adhesion materials. In some embodiments, the wireless tag is affixed to the IC chip using a non-electrically conductive polymer adhesives, such as epoxy based adhesives, polyimide based adhesives, silicone based adhesives or globtop materials.

In the above-described embodiments, the semiconductor packages 30, 40 are shown as housing a single IC chip only. In other embodiments, the embedding method can also be applied to a semiconductor package housing two or more integrated circuits, such as a multi-chip package (MCP). In that case, the wireless tag can be affixed to the top surface of a selected IC chip of the multi-chip package. The selected IC chip can be electrically connected to the package leadframe through wire bonding or through flip-chip attachment. Furthermore, the wireless tag can be affixed to the top surface of the selected IC chip using the wireless-element-up or wireless-element-down orientation.

Furthermore, in the above-described embodiments, the lid-sealed semiconductor package 40 is illustrated as having the integrated circuits flip-chip attached. In other embodiments, a lid-sealed semiconductor package may be formed with the integrated circuit faced up and using bond wires as the interconnects to the package leadframe, in a similar manner to the encapsulated package 30. In that case, the wireless tag can be affixed to the top surface of the selected IC chip using wireless-element-up or wireless-element-down orientation. Furthermore, for either of the affixation orientations, the wire bonds of the semiconductor package should be electrically insulated and/or mechanically secured prior to the wireless tag affixation.

In some embodiments, the wire bonds of a lid-sealed semiconductor package are coated with a protection polymer to ensure electrical insulation from the wireless tag. In one embodiment, the wire bonds are coated with a material selected from epoxy, polyimide, silicone and globtop materials.

### Embed Wireless Tag in Molding Compound

In embodiments of the present invention, a preformed wireless tag is embedded in the molding compound of an encapsulated semiconductor package. In this manner, the wireless tag is completely enclosed and contained inside the encapsulant material of the semiconductor package. In these embodiments, a wireless tag formed on a flexible substrate or a thin rigid substrate may be used.

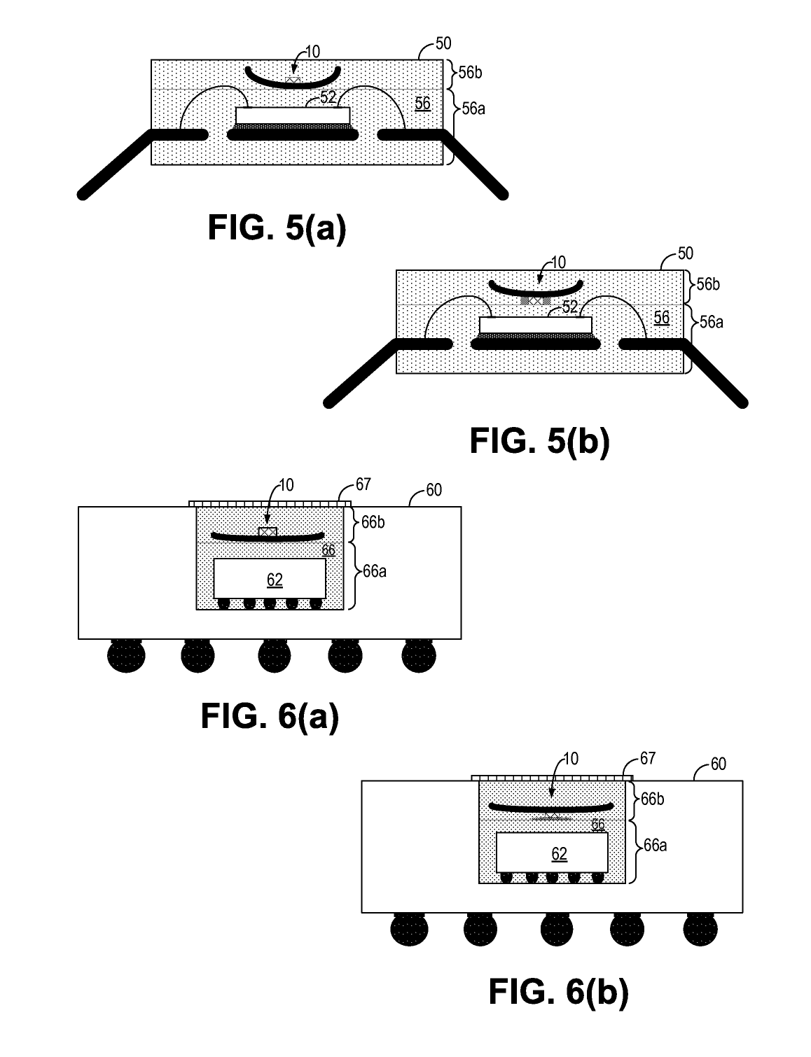

FIGS. 5(a) and 5(b) illustrate two methods of embedding a wireless tag into the encapsulation material of an encapsulated semiconductor package according to embodiments of the present invention. More specifically, the wireless tag can be embedded in the encapsulant of the semiconductor package in one of two orientations—wireless-element-up (FIG. 5(a)) or wireless-element-down (FIG. 5(b)). Referring to FIGS. 5(a) and 5(b), an encapsulated semiconductor package 50 houses an IC chip 52. In one embodiment, the semiconductor package 50 is encapsulated using a plastic encapsulant 56, also referred to as a plastic molding compound formed using a molding process. In one embodiment, the wireless tag 10 is inserted into the semiconductor package before the completion of the molding process. For instance, the molding process can be carried out until a first portion 56a of the molding compound is formed, then the wireless tag 10 is placed on the first portion 56a and the molding process continues to complete the final portion 56b of the molding compound. The wireless tag 10 can be inserted with the wireless element facing up (FIG. 5(a)) or with the wireless element facing down (FIG. 5(b)). In this manner, the wireless tag 10 is incorporated into the semiconductor package 50 completely concealed and is entirely invisible from outside of the package. In one embodiment, the wireless tag 10 is placed on the first portion 56a of the molding compound and affixed to the first portion 56a using an adhesive. In this manner, the wireless tag 10 is mechanically secured to the molding compound before the molding process continues.

In the above-described embodiments, the semiconductor package 50 is shown as housing a single IC chip only. In other embodiments, the embedding method can also be applied to a semiconductor package housing two or more integrated circuits, such as a multi-chip package (MCP). In that case, the wireless tag is embedded in the molding compound used to encapsulate the MCP in the same manner as shown in FIGS. 5(a) and 5(b). Furthermore, the wireless tag can be embedded using the wireless-element-up or wireless-element-down orientation.

### Embed Wireless Tag in Filler Insulator Material

In embodiments of the present invention, a preformed wireless tag is embedded in the filler insulator material of a lid-sealed semiconductor package. In this manner, the wireless tag is completely enclosed and contained inside the filler material of the semiconductor package. In these embodiments, a wireless tag formed on a flexible substrate or a thin rigid substrate may be used.

FIGS. 6(a) and 6(b) illustrate two methods of embedding a wireless tag into the filler insulator material of a lid-sealed semiconductor package according to embodiments of the present invention. More specifically, the wireless tag can be embedded in the filler insulator material of the semiconductor package in one of two orientations—wireless-element-up (FIG. 6(a)) or wireless-element-down (FIG. 6(b)). Referring to FIGS. 6(a) and 6(b), a lid-sealed semiconductor package 60 houses an IC chip 62 in a package cavity using a flip-chip attachment. In one embodiment, the cavity of the semiconductor package 60 is filled with a filler insulator material 66. In some embodiments, the filler insulator material 66 is a material selected from globtop materials, thermal interface materials 2 (TIM2), silicone gels, or other suitable encapsulants.

In one embodiment, the wireless tag 10 is inserted into the semiconductor package before the completion of the cavity filling process. For instance, the cavity filling process can be carried out until a first portion 66a of the filler material is formed in the package cavity, then the wireless tag 10 is placed on the first portion of the filler material and the cavity filling process continues to complete the final portion 66b of the filler material. The wireless tag 10 can be inserted with the wireless element facing up (FIG. 6(a)) or with the wireless element facing down (FIG. 6(b)). In this manner, the wireless tag 10 is incorporated into the semiconductor package 60 completely enclosed. In some embodiments, the package cavity may not be completely filled with filler material. In one embodiment, the wireless tag 10 is placed on the first portion 66a of the filler material and affixed to the first portion 66a using an adhesive. In this manner, the wireless tag 10 is mechanically secured to the filler material before the filling process continues.

### Affix Wireless Tag on MCP Substrate

In embodiments of the present invention, a wireless tag is embedded in a multi-chip package (MCP) housing two or more IC chips by being affixed to the MCP base.

In the present description, a “multi-chip package” or “MCP” refers to a packaging configuration containing two or more integrated circuit (IC) chips or die housed in a semiconductor package, most often a standard single-chip package, so that the MCP appears as if all of the IC chips of the MCP were integrated and packaged as a single die. To describe MCP in more details, in some MCP packages, the IC chips are electrically connected to a multilayer interconnect substrate with interconnects between the IC chips formed thereon. The multilayer interconnect substrate can be formed as a laminate, such as a printed circuit board, or formed using ceramic or silicon or glass. The IC chips can be connected to the multilayer interconnect substrate through wire bonding or through flip-chip bonding or solder bump or gold bump or conductive adhesive bonding to preformed bonding pads on the multilayer interconnect substrate. In other cases, the IC chips are attached to a die paddle with inter-die connections formed through wire bonds and interconnects. The IC chips may be attached to a single die paddle or to a “split pad” die paddle with separate die pads for the individual IC chips. In the present description, the die paddle and the multilayer interconnect substrate on which the IC chips are attached are collectively referred to as a “MCP base.”

The MCP may be protected by an encapsulant or left unencapsulated. When encapsulated, the encapsulant can be a polymer molding compound or equivalent polymers. The MCP can be formed using a ceramic package body, a plastic package body, or a metal package body. In the present description, the “MCP package body” refers to the housing in which the MCP base, the lead frame or bonding pads associated with interconnects, and the external leads (balls or pins) are formed.

When the MCP base is a multilayer interconnect substrate, the dies are electrically connected to the metal interconnects formed in the MCP base which realize high density die-to-die routing. The IC chips can be electrically connected to the MCP base through wire bonding or through flip-chip bonding or solder bump or gold bump or conductive adhesive bonding to preformed bonding pads on the MCP base. In some cases, for extremely simple MCP configuration, the die-to-die routing can be implemented inside the MCP package body using bond wires instead of using a multilayer interconnect substrate.

An MCP operates as if all the chips were integrated into one single die and packaged as such, since the same form factor and footprint are kept to facilitate subsequent board assembly operations. MCPs can also incorporate the use of passive components. The finished form of an MCP is often referred to as an “MCP or MCM module” and can be in a variety of package forms, such as plastic quad flat packages (PQFP) or plastic ball grid array (BGA) multi-chip packages, or ceramic BGA packages or chip-on-board (COB) multi-chip packages or other appropriate semiconductor package forms. In the present description, an “MCP” or an “MCP module” or an “MCM module” refers to the encapsulated or unencapsulated IC package housing an MCP base and including two or more integrated circuit chips formed thereon where the integrated circuit chips may or may not be electrically interconnected.

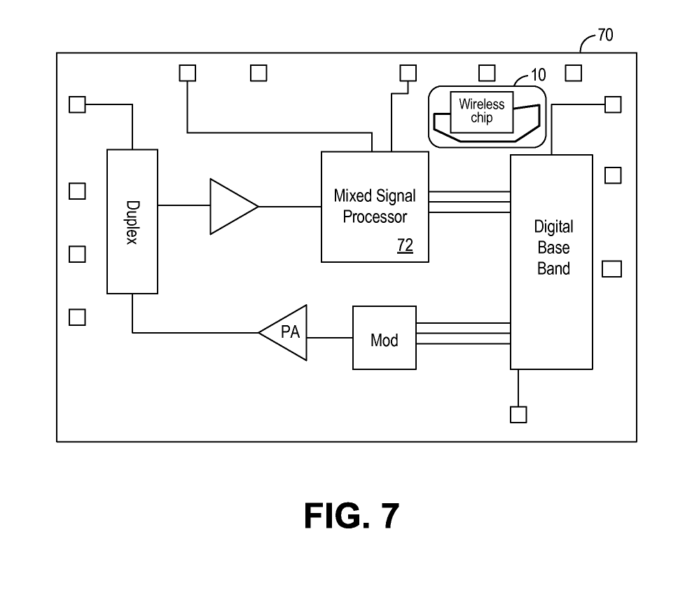

FIG. 7 is a schematic diagram of a MCP base incorporating a wireless tag according to one embodiment of the present invention. Referring to FIG. 7, a MCP base 70 includes multiple IC chips formed thereon, such as IC chip 72. A wireless tag 10, which includes a wireless element affixed to an antenna structure all formed on a flexible substrate, is inserted into the MCP module or is affixed to the MCP base. In one embodiment, the wireless tag 10 is inserted in the encapsulation material of the MCP module used to encapsulate the MCP base, as described above. The encapsulation material for the MCP can include plastic molding compounds or filler materials, such as thermal interface material 2 (TIM2). The wireless tag 10 is inserted or affixed in such a way so as not to interfere with any interconnection formed on the MCP base or on the lead frame of the MCP module.

In another embodiment, the wireless tag 10 is affixed to the MCP base 70 before the encapsulation process, if any, as shown in FIG. 7. In some embodiments, the wireless tag is affixed to the MCP base 70 using adhesion methods such as epoxy adhesion or equivalent adhesion processes. Then the MCP semiconductor package is completed either by encapsulating or by sealing with a lid. In this manner, a wireless tag is fully contained within a MCP module.

In one embodiment, the wireless tag 10 store at least identity or identification information of the MCP module, or of a designated integrated circuits of the MCP module, or of one or more integrated circuits of the MCP module. In this manner, the wireless tag 10 may be used to track and authenticate the MCP module or one or more integrated circuit in the MCP module and the derivative systems incorporating the MCP.

Information stored in the wireless tag 10 may be accessed through a wireless reader. Alternately, information stored in the wireless tag 10 can be accessed wirelessly by a transceiver (not shown) formed on MCP base 70. The designated IC chip 72 of the MCP module can then access the retrieved information through the transceiver and the IC chip 72 can communicate the retrieved information through wired or wireless network using the communication function of the MCP module.

In the above-described embodiments, the MCP module is shown incorporating a mixed signal processor chip. The embodiments described above are illustrative only and are not intended to be limiting. In fact, the MCP module may include any types of integrated circuit chips performing any functions. For instance, in other embodiments, the MCP module may be configured as an electronic module, as an electro-optic module, an electro-mechanical module or an electro-chemical module, or any combination thereof. Typical MCP modules are used to incorporate microprocessor chip set, graphic chip set, wireless communication chip set, chemical sensor module, gas sensor module, image sensor module, or power regulation module.

### Affix Wireless Tag to Inside Package Lid

In embodiments of the present invention, a preformed wireless tag is embedded in a semiconductor package by being affixed to an inside surface of the package lid of a lid-sealed semiconductor package. In this manner, the wireless tag is completely enclosed and contained inside the package cavity of the lid-sealed semiconductor package. In these embodiments, a wireless tag formed on a flexible substrate or a thin rigid substrate may be used.

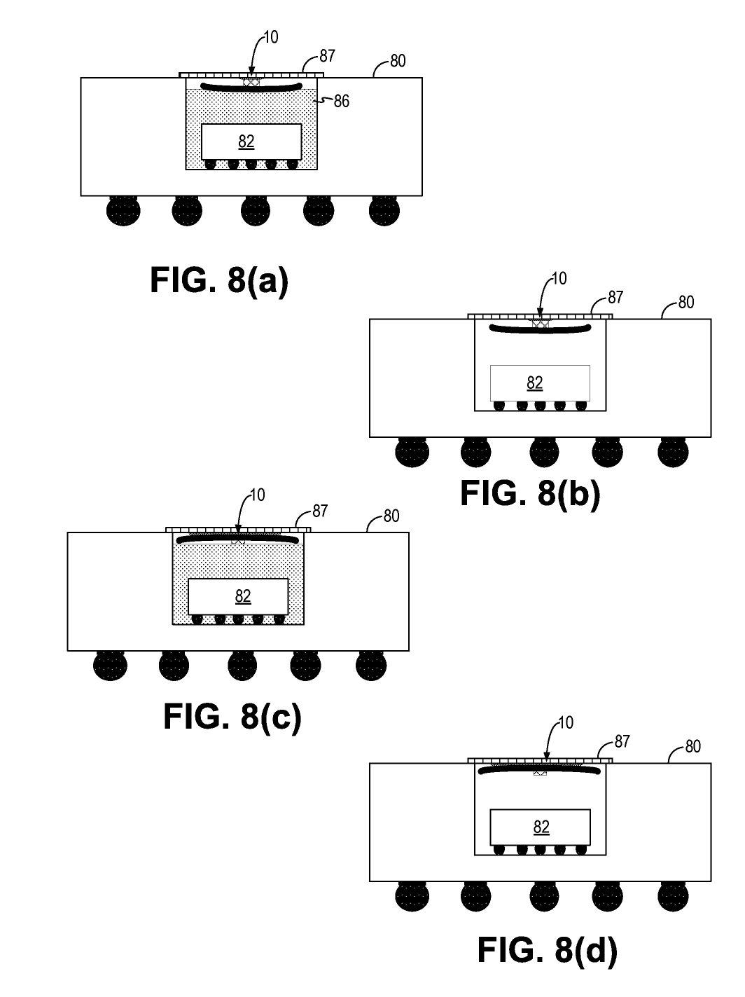

FIGS. 8(a) to 8(d) illustrate methods of embedding a wireless tag into a lid-sealed semiconductor package according to embodiments of the present invention. Referring to FIGS. 8(a) to 8(d), a lid-sealed semiconductor package 80 houses an IC chip 82 in a package cavity using a flip-chip attachment. The cavity of the semiconductor package 80 may be filled with a filler insulator material 86, as shown in FIGS. 8(a) and 8(c). Alternately, the cavity may be left unfilled, as shown in FIGS. 8(b) and 8(d). In some embodiments, the filler insulator material 86 is a material selected from globtop materials, thermal interface materials 2 (TIM2), silicone gels, or other suitable encapsulants.

According to embodiments of the present invention, the wireless tag 10 is first affixed to the package lid 87 of the lid-sealed semiconductor package. In one embodiment, the wireless tag 10 is affixed to the package lid 87 by affixing the wireless element of the wireless tag to the package lid 87, as shown in FIGS. 8(a) and (b). Alternately, the wireless tag 10 is affixed to the package lid 87 by affixing the flexible or rigid substrate of the wireless tag to the package lid 87, as shown in FIGS. 8(c) and (d). This results in the wireless-element-up orientation (FIGS. 8(a) and 8(b)) or the wireless-element-down orientation (FIGS. 8(c) and (d)). After affixing the wireless tag 10 to the package lid 87, the package lid 87 can then be applied to seal the cavity of the semiconductor package 80. The package lid can be made of various materials, including plastic, ceramic, glass, metal or other suitable materials to be developed. The wireless tag 10 is affixed to the package lid using adhesion methods such as epoxy adhesion or equivalent adhesion processes

In the case when a filler material 86 is used to fill the package cavity, the filler material 86 is applied only to partially fill the package cavity so as to leave room to accommodate the wireless tag affixed to the package lid, as shown in FIGS. 8(a) and 8(c).

### Affix Wireless Tag to Chip Scale Package

In embodiments of the present invention, a preformed wireless tag is affixed and encapsulated onto a chip-scale package. In some embodiments, the wireless tag may be fabricated with ultra thin form factor, such as less than 0.25 mm thick. In other embodiments, the wireless tag may have a thickness of less than 0.1 mm thick. The wireless tag thus formed can be embedded to the chip-scale package without altering the physical dimension of the chip-scale package significantly. In these embodiments, a wireless tag formed on a flexible substrate or a thin rigid substrate may be used.

In the present description, a “chip scale package” (CSP) refers to a semiconductor package that is very close to the size of the IC chip. For instance, the package has an area no greater than 1.2 times that of the IC chip and is a single-die, direct surface mountable package. In some cases, a chip scale package includes a bare IC chip fabricated with a build-up thin film interposer containing flip-chip bumps or surface mount solder bumps for external connection.

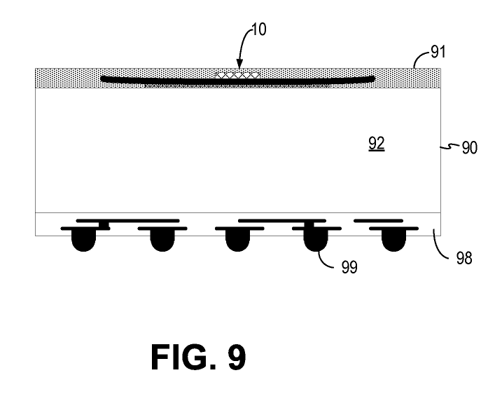

FIG. 9 illustrate a method for embedding a wireless tag onto a chip scale package according to one embodiment of the present invention. Referring to FIG. 9, a chip scale package 90 includes an IC chip 92 covered with a build-up thin film interposer 98 containing conductive bumps 99. A wireless tag 10 is affixed to at least the backside of the IC chip 92 of the chip scale package 90. In one embodiment, after the wireless tag 10 is affixed to the chip scale package 90, the wireless tag 10 can be covered with a thin layer of encapsulant 91. The encapsulant 91 may be colored so as to camouflage the wireless tag affixation. As thus constructed, the wireless tag 10 affixed to the chip scale package 90 and covered by the encapsulant 91 forms a monolithic chip scale package unit with IC chip 92. A slight increase in the thickness of the chip scale package 90 results but the thickness increase is not in the critical dimensions of the chip scale package and such increase in thickness of the chip scale package can be tolerated in most applications.

In some embodiments, the wireless tag 10 is formed on a flexible substrate and the substrate is extended and folded over onto the sides of the IC chip 92. In this manner, an extended antenna structure may be used to increase the accessible range of the wireless tag.

Alternately, in another embodiment, the wireless tag 10 is first encapsulated in an encapsulant, such as a plastic molding compound. In some embodiments, the total thickness of the encapsulated wireless tag unit is less than 0.25 mm, and could be less than 0.1 mm. The encapsulated wireless tag is then affixed to the backside of the IC chip 92 of the chip scale package 90 to form a single package unit. The encapsulated wireless tag can be affixed to the CSP with a wireless-element-up or wireless-element-down orientation. Again, a slight increase in the thickness of the chip scale package results but such thickness increase can be tolerated in most applications.

### Affix Wireless Tag to TSV 3D Semiconductor Package

In embodiments of the present invention, a preformed ultrathin wireless tag is affixed to a Through Silicon Vias (TSV) three dimensional (3D) semiconductor package. In some embodiments, the wireless tag is ultra thin and bendable. The wireless tag may have a total thickness of less than 0.25 mm. In some embodiments, the ultra thin wireless tag has a thickness of no more than 0.1 mm. In the present description, a TSV three dimensional (3D) semiconductor package refers to a package with IC chips stacked in the vertical direction and electrically connected together through the TSV vias 102, as opposed to being placed side-by-side as in an MCP module. The TSV 3D semiconductor package stack are formed on a thin film interposer containing flip-chip bumps or surface mount solder bumps or gold bumps for external connection. More specifically, the flip-chip bumps, solder bumps or gold bumps form the package lead of the TSV 3D semiconductor package.

The embedding method of the present invention allows a wireless tag to be embedded in a TSV 3D semiconductor package without altering appreciably the form factor and the performance of the TSV 3D semiconductor package. In other embodiments, the ultrathin wireless tag can also be applied to other types of 3D semiconductor packages. In these embodiments, a wireless tag formed on a flexible substrate or a thin rigid substrate may be used.

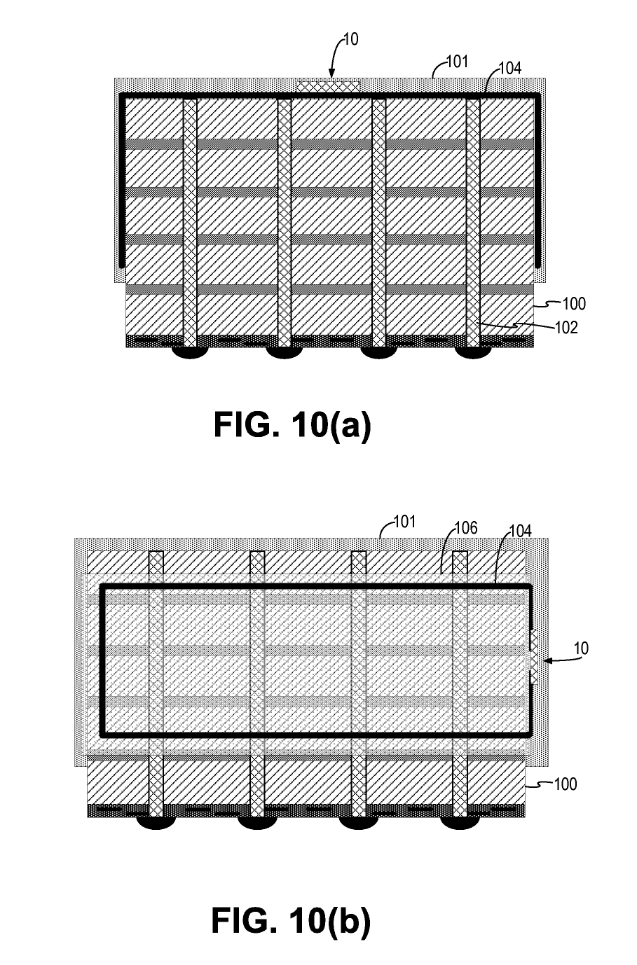

FIGS. 10(a) and 10(b) illustrate two methods of embedding a wireless tag onto a TSV 3D semiconductor package according to embodiments of the present invention. Referring first to FIG. 10(a), a wireless tag 10 is affixed to at least a top surface of a TSV 3D semiconductor package 100. The wireless tag 10 is then encapsulated by an encapsulant 101 to protect and conceal the wireless tag. The TSV 3D semiconductor package as formed, including the wireless tag affixed thereto, functions as a monolithic package. The encapsulant 101 may be a plastic molding compound or other suitable encapsulant materials. The encapsulant 101 may also be colored to better conceal the wireless tag affixation. In one embodiment, the total thickness of the as-encapsulated wireless tag layer may be less than 0.25 mm, or less than 0.1 mm.

In one embodiment, the substrate 106 is a flexible substrate and the substrate including the antenna structure 104 formed thereon is extended and folded over onto the sides of the 3D semiconductor package 100. In this manner, an extended antenna structure may be used to increase the accessible range of the wireless tag. In the case when the flexible substrate 106 is extended to the sides of the TSV 3D semiconductor package 100, the encapsulant 101 also extends to cover all sides of the TSV 3D semiconductor package 100 so as to conceal and protect the wireless tag 10. In other embodiments, when wireless tag 10 is formed of a rigid substrate, the wireless tag will be disposed on a single surface of the 3D semiconductor package 100 and will not be bended over to the other sides.

In the above-described embodiment, the wireless tag 10 is affixed to the top surface of the TSV 3D semiconductor package. In other embodiments, the wireless tag 10 can be affixed to the side surfaces of the 3D semiconductor package, as shown in FIG. 10(b). Furthermore, the antenna structure 104 formed on the flexible substrate may also be extended to other side surfaces of the TSV 3D semiconductor package. Finally, the encapsulant 101 may cover all surfaces of the 3D semiconductor package 100 but the encapsulant is not essential for the surface containing the package leads, such as solder bumps or gold bumps.

The above detailed descriptions are provided to illustrate specific embodiments of the present invention and are not intended to be limiting. Numerous modifications and variations within the scope of the present invention are possible. The present invention is defined by the appended claims.

I claim:

1. A wireless tag for tracking identity or identification information, comprising:
a flexible thin film substrate;
an antenna structure formed on the flexible thin film substrate; and
a wireless element including a wireless transceiver and a memory circuit formed on one or more integrated circuit chips, the wireless element being affixed to the flexible substrate and electrically connected to the antenna structure, the memory circuit having at least identity or identification information stored thereon,
wherein the wireless transceiver and the antenna structure operate in conjunction to enable the information stored in the memory circuit to be accessed through wireless communication.

2. The wireless tag of claim 1, wherein the flexible thin film substrate is formed of a polymer film.

3. The wireless tag of claim 2, wherein the flexible thin film substrate is formed of a material selected from polyethylene terephthalate (PET), Kapton, polyimide or mylar flexible polymer film.

4. The wireless tag of claim 1, wherein the antenna structure comprises a single layer of metal film formed on the flexible thin film substrate.

5. The wireless tag of claim 1, wherein the antenna structure comprises a multi-layer metal structure with intercalated dielectric films formed on the flexible thin film substrate.

6. The wireless tag of claim 1, further comprising a passivation layer formed over the antenna structure.

7. The wireless tag of claim 1, wherein the one or more integrated circuit chips of the wireless element are affixed to the flexible substrate through flip-chip attachment.

8. The wireless tag of claim 1, wherein the one or more integrated circuit chips of the wireless element are affixed to the flexible substrate using die attach, the one or more integrated circuit being electrically connected to the antenna structure and to each other through wire bonds.

9. The wireless tag of claim 8, wherein the wire bonds for electrically connecting the one or more integrated circuits to the antenna structure and each other are covered with a protective layer selected from one of a polymer material, an epoxy, a silicone material and a globtop material.

10. The wireless tag of claim 1, wherein the wireless transceiver comprises a radio frequency (RF) transceiver.

11. A method for providing identity tracking and authentication for a multi-chip package (MCP) module or one or more integrated circuits formed on a multi-chip package (MCP) base of the MCP module, the method comprising:
providing a wireless tag comprising a wireless element including a wireless transceiver and a memory circuit formed on one or more integrated circuits, the wireless element being affixed to a flexible substrate having an antenna formed thereon, the wireless element being electrically connected to the antenna, the memory circuit having at least identity or identification information stored thereon, wherein the wireless transceiver and the antenna structure operate in conjunction to enable the information stored in the memory circuit to be accessed through wireless communication;
affixing the wireless tag to the MCP base of the MCP module; and
completing the MCP module with the wireless tag and the one or more integrated circuits enclosed therein.

12. The method of claim 11, wherein affixing the wireless tag to the MCP base of the MCP module comprises affixing the wireless tag to the MCP base of the MCP module using an adhesive.

13. A multi-chip package (MCP) module including one or more integrated circuits formed on an MCP base of the MCP module, the MCP module comprising:
a wireless tag comprising a wireless element including a wireless transceiver and a memory circuit formed on one or more integrated circuits, the wireless element being affixed to a flexible substrate having an antenna formed thereon, the wireless element being electrically connected to the antenna, the memory circuit having at least identity or identification information stored thereon, wherein the wireless transceiver and the antenna structure operate in conjunction to enable the information stored in the memory circuit to be accessed through wireless communication,
wherein the wireless tag is affixed to the MCP base of the MCP module.

14. The MCP module of claim 13, wherein the wireless tag is affixed to the MCP base of the MCP module using an adhesive.
